(19) United States
(12) Patent Application Publication
(10) Pub. No.: US 2016/0315003 A1
(43) Pub. Date: Oct. 27, 2016

(54) WAFER BOAT

(71) Applicant: CENTROTHERM PHOTOVOLTAICS AG, Blaubeuren (DE)

(72) Inventors: Andreas Reichart, Berghülen (DE); Andreas Keller, Opfingen (DE)

(21) Appl. No.: 15/105,792

(22) PCT Filed: Dec. 19, 2014
(86) PCT No.: PCT/EP2014/078902

§ 371 Date: Jun. 17, 2016

(30) Foreign Application Priority Data
Dec. 20, 2013 (DE) 102013021922.1
Feb. 19, 2014 (DE) 102014002280.3

(51) Int. Cl. H01L 21/673; H01L 21/67

(52) U.S. Cl. CPC H01L 21/67316; H01L 21/67109

(57) ABSTRACT

A wafer boat for receiving wafers, in particular semiconductor wafers, includes at least two elongated receiving elements made of quartz, each receiving element having a plurality of parallel receiving slots, which extend transverse to the longitudinal extension of the receiving elements, and two end plates, between which the receiving elements are arranged and attached such that the receiving slots of the receiving elements are aligned. For increasing the stability, the wafer boat includes a plurality of attachment pieces, via which the receiving elements are attached to the end plates, wherein each attachment piece has a circumference which is at least 1.5 times as large as the circumference of a receiving section of the receiving elements comprising the receiving slots, and wherein each attachment piece is welded or bonded to at least one of the following: an end plate and a receiving element. In a further embodiment, which may be combined with the above, the receiving elements each have at least one relaxation slot adjacent to the end plates, preferably at least two relaxation slots having a depth, which is smaller than the depth of the receiving slots. When at least two relaxation slots are provided, the depth thereof increases with increased distance to the end plates.

### RELATED APPLICATIONS

This application corresponds to PCT/EP2014/078902, filed Dec. 19, 2014, which claims the benefit of German Applications Nos. 10 2013 021 922.1, filed Dec. 20, 2013 and 10 2014 002 280.3, filed Feb. 19, 2014, the subject matter of which are incorporated herein by reference in their entirety.

### BACKGROUND OF THE INVENTION

The present invention relates to a wafer boat for receiving and holding thin wafers, in particular semiconductor wafers, wherein the term wafer as used herein generally refers to thin disc shaped substrates of arbitrary circumferential shape.

Wafer boats are often used to support a plurality of wafers in a processing device, such as a diffusion device for semiconductor wafers, in which the semiconductor wafers are exposed to thermal processes. The wafer boats have to withstand thermal stresses due to the thermal processes and also mechanical stresses due to supporting the wafers and also due to the loading and unloading of the wafers. Furthermore, the wafer boats are also exposed to the respective process atmospheres, to which the wafers are exposed. Therefore, the processes should possibly not adversely affect the wafer boats over time. Generally it is not only desired that the wafer boats are not adversely affected by the respective processes, but also that the wafer boats themselves do no adversely affect the processes. In particular in the semiconductor technology, care has to be taken that the wafer boats do not introduce contaminations into the process.

Thus, in the past, for example wafer boats made of quartz were used, which on the one hand unsusceptible are to most processes and on the other hand do not introduce contaminations into the semiconductor process. However, there is a need to use larger and larger quartz boats, in order to achieve a larger mass loading of the processing device. In particular, a higher throughput of wafers per process run is to be achieved. This may, for example, be achieved by lengthening the boats and/or by reducing the slot distances or the pitch between adjacent slots for receiving wafers, such that the number of received wafers per boat increases. Hereby, the overall mass of the loaded wafers increases, wherein the mass of the wafer boat preferably should not increase in the same manner. Preferably, a fully loaded wafer boat should be able to receive multiple times (preferably at least three times) the mass of wafers compared to the mass of the wafer boat. A reduced mass of the wafer boat enables energy savings during the thermal processing and furthermore enables quicker heating and cooling cycles. In particular in the region where the wafers are received, the wafer boat should be as delicate as possible in order to ensure a small amount of shading of the wafers and thus a homogeneous processing thereof.

There is, however, the problem that the quartz material, which is known to be a brittle material, may not be able to withstand the mechanical stresses. This is in particular true, since each mechanical machining, for example for forming the receiving slots, leads to an infraction of the material, which may lead to micro-fissures (notching effect/stress concentration).

Therefore, in the past, silicon infiltrated silicon carbide (Si—SiC) was used as the material for large wafer boats in lieu of quartz. Such wafer boats have good mechanical characteristics. However, they do not tolerate large temperature differences, which may, however, occur during the thermal processing due to the geometry. This problem is also known under the term resistance to thermal shock. In particular, in such boats thermal stress fractures occur more often in processes which get faster and faster. Furthermore, the material sometimes introduced undesired contaminations into the process and wafer boats made of Si—SiC are substantially more expansive than wafer boats made of quartz. This is inter alia due to the fact that silicon infiltrated silicone carbide has a low availability and the machining thereof is expensive.

### SUMMARY OF THE INVENTION

It is therefore an object of the present invention to provide a wafer boat which overcomes at least one of the above mentioned shortcomings.

In accordance with the invention a wafer boat in accordance with claim 1 or claim 3 and an apparatus for treating semiconductor wafers in accordance with claim 3 are provided.

One embodiment of the wafer boat comprises at least two elongated receiving elements made of quartz, which each comprise a plurality of parallel receiving slots, which extend transverse to the extension of the receiving elements, as well as two end plates, between which the receiving elements are arranged and attached such that the receiving slots of the receiving elements are aligned, as is known in the art. In accordance with the invention, the wafer boats comprise a plurality of attachment pieces, via which the receiving elements are attached to the end plates, wherein each attachment piece has a circumference which is at least 1.5 times as large as the circumference of the receiving section of the receiving elements comprising the receiving slots, and wherein each attachment piece is welded or bonded to at least one of the following: an endplate and a receiving element. By means of such an attachment piece, stresses, in particular mechanical stresses in the area of the attachment may be better distributed, such that the danger of breakage at this location is substantially reduced. With such a configuration, even for larger wafer boats made of quartz, for example, having a length of larger than one meter, a sufficient stability may be achieved. But also with wafer boats having shortened slot distances, for example a so called half pitch, an Improved stability may be achieved. Quartz is advantageous due to the low potential to introduce contaminations, and also due to its high availability over other materials such as for example Si—SiC. In one embodiment of the invention, the circumference of the attachment piece is at least twice the circumference of the receiving section of the receiving elements comprising the receiving slots.

In another embodiment the receiving elements have adjacent to the attachment piece at least one relaxation slot preferably at least two relaxation slots having a depth, which is smaller than the depth of the receiving slots. When two or more relaxation slots are present, the depth thereof increases with increased distance to the attachment piece. Hereby, stresses generated due to the receiving and relaxation slots, in particular mechanical stresses, may be belter introduced into the receiving element.

An alternative embodiment of the wafer boat again comprises at least two elongated receiving elements made of quartz, which each comprise a plurality of parallel receiving slots, which extend transverse to the extension of the receiving elements, as well as two end plates, between which the receiving elements are arranged and attached, such that the receiving slots of the receiving elements are aligned to each other. In this embodiment, the receiving elements each comprise at least relaxation slot adjacent to the end plates, having a depth, which is smaller than the depth of the receiving slots. Hereby, the mechanical stresses occurring due to the receiving slots and the relaxation slots may be better introduced into the receiving element. Such a wafer boat may also preferably have the above cited attachment pieces, having an enlarged circumference. In one embodiment, for a softer introduction of the stresses at least two relaxation slots are provided, wherein the depth thereof increases with increased distance to the end plates.

Preferably, each attachment piece is an integral part of the end plate or of the receiving element and is welded or bonded to the other element. Welding is performed preferably at the circumference of the element having the smaller circumference. In a preferred embodiment each attachment piece is an integral part of the end plate and is formed by milling or machining a plate element forming the end plate and the attachment piece. In an alternative embodiment each attachment piece Is a separate element, which is welded or bonded both to an end plate and a receiving element. This embodiment enables a simple manufacture of the individual components.

Preferably, each attachment piece has a plate shape, and the transition region to at least one of the end plate and the receiving element is formed by at least one monotonically widening section. Hereby, stress peaks, in particular mechanical stress peaks at abrupt transitions may be avoided. In particular, the transition region may describe the radius of a circle. The plate shape furthermore prevents an overly large mass of material in the area of the attachment pieces, which could lead to thermal stress during a heating/cooling of the wafer boat. The attachment piece preferably has a depth in the direction of extension of the receiving elements, which is smaller than four times the distance between the receiving slots and preferably smaller than three times the distance, wherein the distance is measured between the centres of the slots.

In one embodiment the receiving section of the receiving elements comprises a substantially rectangular cress section, wherein the receiving elements are tilted towards each other by 45° with respect to the horizontal. By means of the rectangular shape and the arrangement, a good stability may be achieved, while compare to round elements, the mass of the materiel may be reduced.

Besides the receiving elements, which are supposed to support the wafers in the wafer boat, at least one elongated guide element made of quartz and having a plurality of guide slots, corresponding to the receiving slots in the receiving elements, is provided. The at least one guide element extends parallel to the receiving elements and is attached between the end plates. By means of additional guide slots, tipping of the wafers in the longitudinal direction of the wafer boat may be prevented, wherein again, preferably quartz may be used.

In accordance with the invention, also an apparatus for treating semiconductor wafers is provided, which apparatus comprises at least one wafer boat of the above described type, at least one process chamber for receiving the at least one wafer boat and at least one heating device for heating semiconductor wafers in the process chamber. Preferably, the apparatus is a diffusion device.

### BRIEF DESCRIPTION OF THE DRAWINGS

The invention will be described herein below with reference to the drawings; in the drawing:

FIG. 1 shows a schematic perspective view of a wafer boat in accordance with the invention;

FIG. 2 is a schematic top view of the wafer boat according to FIG. 1;

FIG. 3 shows a schematic sectional view through the wafer boat;

FIG. 4 shows a schematic detail of the receiving element of the wafer boat;

FIG. 5 shows a perspective, schematic partial view of the wafer boat in the area of an end plate;

FIG. 6 shows a schematic enlarged partial view of the wafer boat; and

FIG. 7 shows a schematic enlarged partial view of an alternative end section of a receiving element for a wafer boat.

### DESCRIPTION

Terms such as above, below, left and right as used throughout the description, refer to the presentation in the drawings and are not intended to be construed in a limiting manner.

In the following, the basic construction of a wafer boat 1 will be explained with reference to the drawings. Within the drawings, the same reference signs are used when describing the same or similar elements.

The wafer boat 1 is in substance formed by end plates 3, receiving elements 5 and guide elements 7.

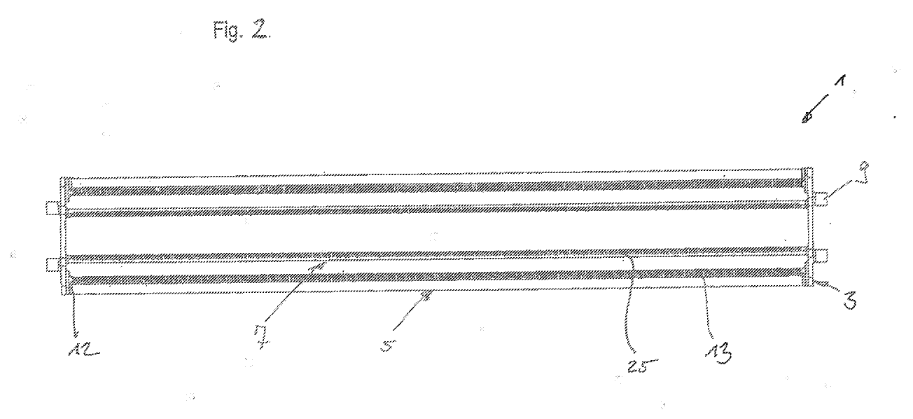

As is for example shown in the top view according to FIG. 2, the wafer boat 1 has an elongated configuration, i.e. it has an extension in its longitudinal direction (left to right in FIG. 2), which has a larger length than the other dimensions. At its ends, the wafer boat 1 is provided with respective end plates 3, which are preferably made of quartz. They may, however, be also formed from a different suitable material. The receiving elements 5 as well as the guide elements 7 extend between the end plates 3, and both are attached to the end plates 3, as will be explained in more detail herein below.

Furthermore, carrier elements 9 are attached to the outwardly facing sides of the end plates 3, which—as is known in the art—allow for an automatic handling of the wafer boats. The end plates 3 have an overall adapted form having different recesses and openings. For example, a lower recess 10 is provided, which may for example enable proper positioning of the wafer boat. Additionally, positioning holes and/or other markings may be provided in or on the end plates 3, which may for example signal the type, the orientation and/or other characteristics of the wafer boat.

The receiving elements 5, as previously mentioned, extend between the end plates 3 and are attached to the same via attachment pieces 12, in particular by welding or bonding, as will be explained in more detail herein below. The receiving elements 5 are made of quartz and each comprises an elongated rod shape. The receiving elements 5 each have an intermediate receiving section and attachment sections at the opposite ends thereof.

The receiving elements 5 have a substantially rectangular cross-sectional shape, wherein “substantially” in particular also includes rectangles having rounded edges. It is, however, also possible that the receiving element is round or has different shapes. In one narrow side of the receiving elements 5 a plurality of receiving slots 13 is formed, which extend transverse to the longitudinal extension of the receiving element 5 and preferably at a 90° angle with respect to the longitudinal extension thereof. The receiving slots 13 are each provided with a constant distance or pitch and they have a predetermined (constant) depth for receiving an edge section of a respective wafer to be received. Preferably, the depth corresponds to an edge rejection region of the wafer or is smaller than the same.

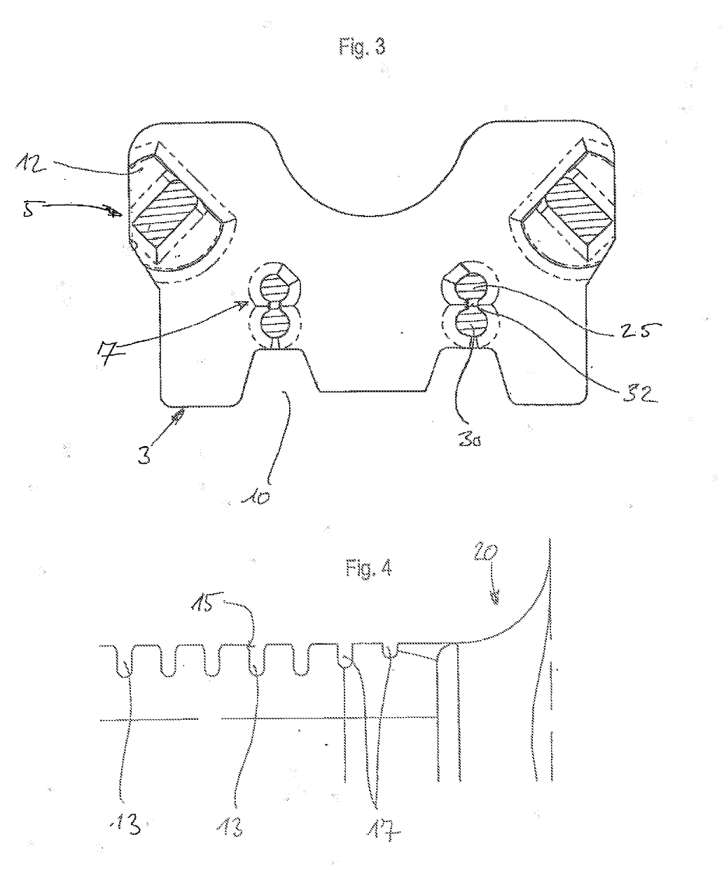

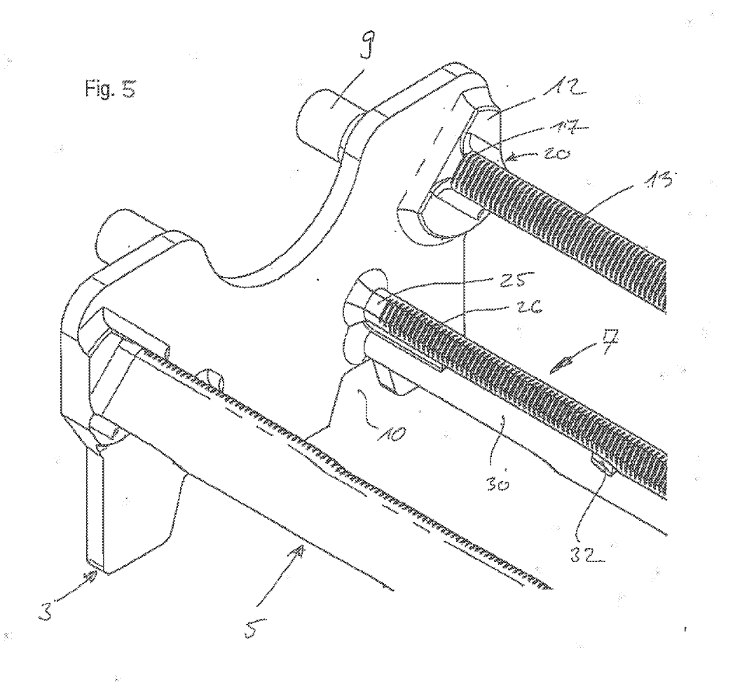

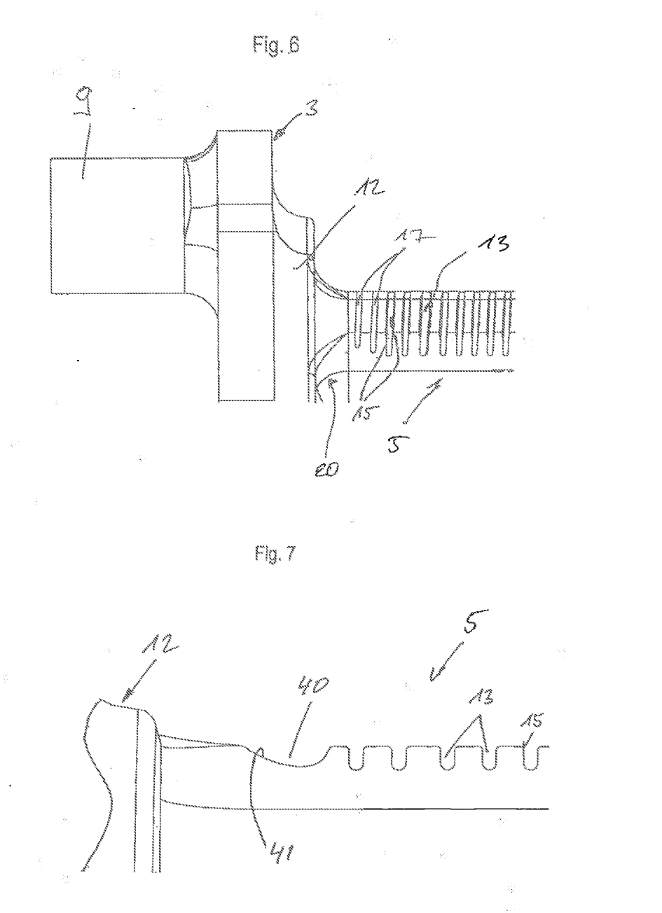

As is best shown in FIG. 4 or FIG. 6, the receiving slots have a taper at their upper ends, which is formed by sloped surfaces 15. The sloped surfaces act as insertion slopes, in order to facilitate insertion of wafers into the receiving slots 13.

Receiving slots 13 are in substance provided over the whole length of the receiving elements 5. Only in the end sections, adjacent to the attachment sections of the receiving elements 5, no receiving slots 13 are provided. In these end sections, two relaxation slots 17 are provided, which do not function as receptacles for the wafer. Therefore, the relaxation slots 17 may also dispense with the insertion slopes 15, which are provided at the receiving slots 13. The relaxation slots 17 furthermore have a depth which is smaller than the depth of the receiving slots 13, which leads to a reduction of mechanical stress. In the shown embodiment (in particular FIG. 4) two of these relaxation slots 17 are shown, however, a larger or smaller number of relaxation slots 17 may be provided. The slot depth of the relaxation slots 17, starting from the last receiving slot 13, decreases towards the attachment piece 12. Stresses which occur are thus lowered in a step wise manner The relaxation slot 17 having a smaller depth facilitates a lower mechanical stress in the first receiving slot 13 during use.

Instead of providing a plurality of relaxation slots 17, also a wider relaxation recess 40 may be provided at this position, as is for example shown in FIG. 7. FIG. 7 shows an end section of a receiving element 5, as well as a portion of an attachment piece 12. The receiving element 5 again has a plurality of receiving slots 13 having slopes 15. In lieu of the relaxation slots, however a wider relaxation recess 40 is provided. The relaxation recess 40 has a sickle shaped bottom 41 having a shallow slope adjacent the attachment piece 12 and a steeper slope adjacent to the first receiving slot 13. The lowest point of the relaxation recess 40 is closer to the end having the steeper slope than to the other end. The depth of the relaxation recess at the lowest point is less than the depth of the receiving slots 13. Such a relaxation recess 40 again allows a soft introduction of stresses, in particular of mechanical stresses into the receiving element 5.

The attachment pieces 12 each have in substance a plate shape and are typically also made of quartz. In the presently preferred embodiment, the attachment pieces 12 are integrally formed with the end plates 3 and are for example formed by milling or machining the same from a plate material forming the end plates. In this embodiment, the receiving elements 5 are then welded or bonded to the attachment pieces in order to achieve attachment to the end plates 3. It is, however, also possible that the attachment pieces 12 are integrally formed with the receiving elements 5 and that the attachment pieces 12 are then welded or bonded to the end plates 3. In a further embodiment the attachment pieces 12 are formed as separate elements and they are welded or bonded both to the end plates 3 and the receiving elements 5. In each case attachment of the receiving elements 5 to the end plates 3 is achieved via respective attachment pieces 12.

Hereby, the transition region 20 between the respective rod shaped receiving elements 5 and the plate shaped attachment piece 12 forms a monotonic widening portion. In particular, the transition region 20 in substance describes a circular arc. This is respectively true for the transition region between the plate-shaped attachment piece 12 and the end plate 3. The radius of the transition region between the attachment piece 12 and the end plate hereby determines the minimal depth of the attachment piece 12 in the longitudinal direction of the receiving element 5. A contemplated depth for the attachment pieces is in the range of 2-20 mm. Preferably, the depth is smaller than four times the distance between the receiving slots and preferably smaller than three times the distance.

Each attachment piece 12 has a substantially larger circumference than the rod-shaped receiving elements 5, in which the receiving slots 13 are formed. Due to this step-wise broadening of the circumference from the receiving element 5 to the attachment piece 12 and the end plate 3, mechanical stress may be minimized. The circumference of the attachment piece 12 is in particular at least 1.5 times as large as the circumference of the rod-shaped receiving element 5. Preferably, the circumference of the attachment piece 12 is at least twice as large as the circumference of the rod-shaped receiving element 5.

When a respective attachment piece 12 is welded to an end plate 3 and/or a receiving element 5, with welding preferably being the preferred attachment method, welding occurs around the circumference of the element having the smaller circumference. The thus formed transition area forms a monotonically widening portion (in the direction of the end plate 3). In particular, this transition portion forms a circular arc.

The rod-shaped receiving elements 5 are attached via the attachment pieces 12 in such a manner to the end plates 3, that the long sides of the rectangular cross section are inclined by 45° to the horizontal such that the small sides comprising the receiving slots 13 are facing towards each other. Hereby, the receiving slots 13 in substance form a 90° angle therebetween.

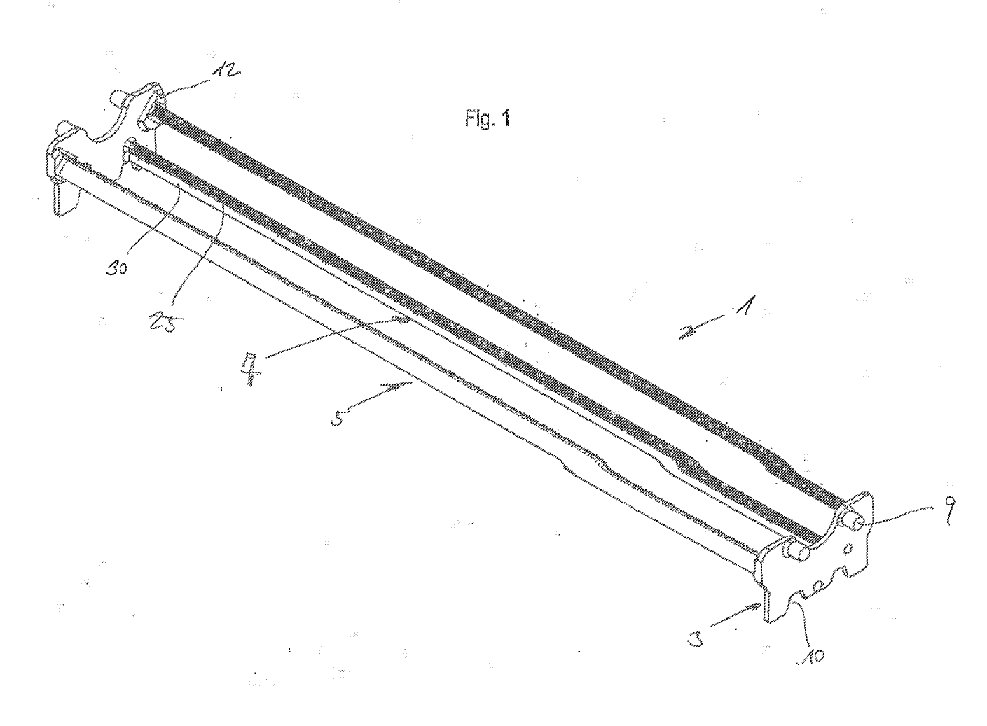

As shown in the top view of FIG. 1, the receiving elements 5 are spaced in a transverse direction of the wafer boat 1, wherein the distance is chosen such that a wafer received in the receiving slot 13 is supported on a respective bottom of one of the receiving slots 13 below Its horizontal middle line. Hereby, forces are generated in the direction of the long and transverse sides of the rod shaped receiving elements 5.

In the following, the guide elements 7 are described in more detail, two of which are shown in the top view of FIG. 1. The guide elements 7 are each formed in substance by a rod-shaped element 25 which are made of quartz and have a plurality of guide slots 26.

The rod-shaped element 25 has a substantially round cross sectional shape as is best seen in the cross section according to FIG. 2. The rod-shaped element 25 may, however, also have a chamfer which is slanted by 45° to the horizontal, as shown, wherein the chamfers of the two rod-shaped elements 25 face towards each other.

In the rod-shaped element 25 a plurality of slots 26 is provided, which are also inclined by 45° with respect to the horizontal and thus extend in substance similar to the receiving slots 13 in the respective neighbouring receiving element 5. The slots 26 have a depth such that wafers, which are received by the receiving elements 5, are not supported on the bottom of the respective slots. Thus, the guide elements 7 typically do not support the wafers and the slots 26 only have a guide function for the wafer in a sideways direction. Thus, the rod-shaped elements 25 may be formed as thin elements, as shown.

In order to provide sufficient stability over the whole length of the wafer boat, in the embodiment as shown, a second rod-shaped element 30 is provided, which is located vertically below the rod-shaped element 25 and which extends between the end plates 3. Between the lower rod-shaped element 30 and the upper rod-shaped element 25 a plurality of supports 32 are provided. The lower rod-shaped element 30 again has a round shape, but neither has a chamfer nor slots. Thus, it has a higher stability and may support the upper rod-shaped element 25 over its length.

Both the upper rod-shaped element 25 and the lower rod-shaped element 30 are welded to the end plate 3 at their ends. Hereby, again a monotonically broadening transition region is formed between the respective rod-shaped element 25, 30 and the end plate 3. In particular, the transition again describes a circular arc. Also here, attachment may occur via a not shown attachment piece, in order to minimize stresses. These could be formed in a similar manner to the attachment pieces 12 and may provide a step-wise increase in circumference, wherein the ratio of the increase in circumference would refer to the respective rod-shaped elements.

The receiving elements 5 and the guide elements 7 are, as best shown in the top view of FIG. 2 or the sectional view of FIG. 3, arranged such that they do not overlap in a vertical direction. In particular, between a respective receiving element 5 and a neighbouring guide element 7, a gap is formed, through which a loading/unloading comb may move. In the same manner a respective gap is also formed between the guide elements 7, which gap is free of any barrier over the complete length of the wafer boat.

In the following, operation of the wafer boat is explained in more detail. An empty wafer boat 1 is initially brought into a loading position in the area of a loading/unloading comb, wherein for example the lower recesses in the end plates 3 act as guide and positioning recesses. Then, loading and unloading combs are moved in a vertical direction between the guide elements 7 and optionally between the receiving elements 5 and the guide elements 7. Unto this comb, wafers are placed, which are then introduced into the respective receiving slots and guide slots of the receiving and guide elements 5, 7 by lowering the loading/unloading comb. The wafers come to rest in the receiving slots and are guided in the guide slots.

Subsequently, such a loaded wafer boat is introduced into a process chamber. In particular, the wafer boat as shown is for example designed for a process chamber of a diffusion oven, in which the wafers are exposed to heat and certain process gases. Since the wafer boat is made of quartz, it is typically not sensitive to heating and the process gas atmosphere. Furthermore, quartz does not introduce contaminations into the process. After a respective treatment of the wafer, the wafer boat is taken out of the process in a reversed order and the wafers are respectively unloaded.

In view of the special attachment of the receiving elements 5, it is, despite the large and free length of the receiving elements 5, possible to use quartz elements. Attachment of the receiving elements 5 via the attachment pieces 12 allows a reduction of the mechanical stress, such that breakage of the receiving elements 5 in the attachment area, which has occurred in the past with wafer boats made of quartz, may be avoided. Hereby, also the soft transition between the rod-shaped receiving elements 5 and the attachment piece 12 is advantageous. Such a breakage may also be avoided by an increase of the slot depth of the relaxation slots 17 starting from the end plates 3, wherein the use of the attachment pieces 12 in combination with the increasing slot depth is particularly advantageous. With respect to the guide elements 7, typically the attachment pieces may be dispensed with as long as they have only guiding functionality. If they are also required to take over a supporting function, they should also be attached to the end plates 3 via respective attachment pieces. Respective attachment pieces may, however, also be provided independent of a supporting function to minimize stresses.

The invention was described above with respect to a preferred embodiment of the invention without being limited to the specific embodiment.

In particular, the cross sectional shapes of the receiving elements as well as of the guide elements may differ from the shown shapes. Furthermore, it is possible to provide a single central guide element instead of or additionally to the two guide elements, which would then in substance have horizontal slots rather than slots which are inclined by 45°.

1.-15. (canceled)

16. A wafer boat for receiving wafers, in particular semiconductor wafers, comprising:
at least two elongated receiving elements made of quartz, each having a plurality of parallel receiving slots, which extend transverse to the longitudinal extension of the receiving elements; and
two end plates, between which the receiving elements are arranged and attached such that the receiving slots of the receiving elements are aligned; wherein the wafer boat comprises a plurality of attachment pieces, via which the receiving elements are attached to the end plates, wherein each attachment piece has a circumference, which is at least 1.5 times as large as the circumference of the receiving section of the receiving elements comprising the receiving slots, and wherein each attachment piece is welded or bonded to at least one of the following: an end plate and a receiving element.

17. The wafer boat according to claim 16, wherein the receiving elements comprise at least one relaxation slot adjacent to the attachment piece, the at least one relaxation slot having a depth, which is smaller than the depth of the receiving slots.

18. The wafer boat according to claim 17, wherein the receiving elements comprise at least two relaxation slots having a depth, which is smaller than the depth of the receiving slots, wherein the depth of the at least two relaxation slots increase with increased distance to the end plates.

19. The wafer boat according to claim 16, wherein each attachment piece is integrally formed with an end plate or a receiving element, and is welded or bonded to the other element.

20. The wafer boat according to claim 18, wherein each attachment piece is integrally formed with the end plate and is formed by milling or machining the same from a plate element.

21. The wafer boat according to claim 16, wherein each attachment piece is a separate element, which is welded or bonded to both an end plate and a receiving element.

22. The wafer boat according to claim 16, wherein each attachment piece comprises a plate shape, and wherein the transition section to at least one of the end plate and the receiving element is formed by a monotonically widening section.

23. The wafer boat according to claim 16, wherein each attachment piece has a depth in the longitudinal extension of the receiving elements, which is in the range of 2-20 mm.

24. The wafer boat according to claim 16, wherein each attachment piece has a depth in the longitudinal direction of the receiving element, which is smaller than four times the distance between the receiving slots and preferably smaller than three times the distance.

25. The wafer boat according to claim 16, wherein the receiving section of the receiving elements comprises a substantially rectangular cross sectional shape wherein the receiving elements are inclined by 45° to the horizontal towards each other.

26. The wafer boat according to claim 18, further composing an elongated guide element made of quartz having a plurality of guide slots, corresponding to the receiving slots in the receiving elements, which guide element is attached between the end plates in parallel to the receiving elements.

27. A wafer boat for receiving wafers, in particular semiconductor wafers, comprising:
at least two elongated receiving elements made of quartz, each having a plurality of parallel receiving slots, which extend transverse to the longitudinal extension of the receiving elements; and
two end plates, between which the receiving elements are arranged and attached such that the receiving slots of the receiving elements are aligned; wherein the receiving elements comprise at least one relaxation slot adjacent to the end plates, the at least one relaxation slot having a depth, which is smaller than the depth of the receiving slots.

28. The wafer boat according to claim 27, wherein the receiving elements comprise at least two relaxation slots having a depth, which is smaller than the depth of the receiving slots, wherein the depth of the at least two relaxation slots Increase with increased distance to the end plates.

29. The wafer boat according to claim 27, wherein the wafer boat comprises a plurality of attachment pieces, via which the receiving elements are attached to the end plates, wherein each attachment piece has a circumference which is at least 1.5 times as large as the circumference of a receiving section of the receiving elements having the receiving slots, and wherein each attachment piece is welded or bonded to at least one of the following: an end plate and a receiving element.

30. The wafer boat according to claim 29, wherein each attachment piece is integrally formed with an end plate or a receiving element, and is welded or bonded to the other element.

31. The wafer boat according to claim 30, wherein each attachment piece is integrally formed with the end plate and is formed by milling or machining the same from a plate element.

32. The wafer boat according to claim 29, wherein each attachment piece is a separate element, which is welded or bonded to both an end plate and a receiving element.

33. The wafer boat according to claim 29, wherein each attachment piece comprises a plate shape, and wherein the transition section to at least one of the end plate and the receiving element is formed by a monotonically widening section.

34. The wafer boat according to claim 29, wherein each attachment piece has a depth in the longitudinal extension of the receiving elements, which is in the range of 2-20 mm.

35. The wafer boat according to claim 29, wherein each attachment piece has a depth in the longitudinal direction of the receiving element, which is smaller than four times the distance between the receiving slots and preferably smaller than three times the distance.

36. The wafer boat according to claim 27, wherein the receiving section of the receiving elements comprises a substantially rectangular cross sectional shape wherein the receiving elements are inclined by 45° to the horizontal towards each other.

37. The wafer boat according to claim 27, further comprising an elongated guide element made of quartz having a plurality of guide slots, corresponding to the receiving slots in the receiving elements, which guide element is attached between the end plates in parallel to the receiving elements.

38. An apparatus for treating semiconductor wafers, comprising:
at least one wafer boat according to claim 16,
at least one process chamber for receiving at least one wafer boat,
at least one heating device for heating semiconductor wafers in the process chamber.

39. The apparatus for treating semiconductor wafers according to claim 27, wherein the apparatus is a diffusion device.
